(19) United States
(12) Patent Application Publication
(10) Pub. No.: US 2024/0387234 A1
(43) Pub. Date: Nov. 21, 2024

(54) SUBSTRATE SUPPORT APPARATUS AND SUBSTRATE PROCESSING APPARATUS HAVING THE SAME

(71) Applicant: SAMSUNG ELECTRONICS CO., LTD., SUWON-SI (KR)

(72) Inventors: JUNHYUNG KIM, Suwon-si (KR); INSEOK SEO, Suwon-si (KR)

(21) Appl. No.: 18/621,273

(22) Filed: Mar. 29, 2024

(30) Foreign Application Priority Data
May 16, 2023 (KR) 10-2023-0062826

(51) Int. Cl. H01L 21/687; H01J 37/32; H01L 21/683

(52) U.S. Cl. CPC H01L 21/68757; H01L 21/6833; H01L 21/6875; H01L 21/68785; H01J 37/32724; H01J 2237/334

(57) ABSTRACT

A substrate support apparatus includes a base plate disposed in a space for performing a semiconductor process, a substrate stage disposed apart from the base plate, the substrate stage having a seating surface on an upper surface of the substrate stage, and a plurality of support structures arranged in a circumferential direction on the base plate to support the substrate stage on the base plate, the plurality of support structures extending in a radial direction to have a predetermined inclination angle from a surface of the base plate.

### CROSS-RELATED TO RELATED APPLICATION

This application claims priority under 35 U.S.C. § 119 to Korean Patent Application No. 10-2023-0062826, filed on May 16, 2023, in the Korean Intellectual Property Office (KIPO), the contents of which are herein incorporated by reference in their entirety.

### TECHNICAL FIELD

Example embodiments relate to a substrate support apparatus and a substrate processing apparatus including the same. More particularly, example embodiments relate to a substrate support apparatus configured to support a semiconductor substrate during a semiconductor process and a substrate processing apparatus including the same.

### DISCUSSION OF RELATED ART

In a semiconductor manufacturing process such as an etching process, a semiconductor substrate may be supported by an electrostatic chuck (ESC). The electrostatic chuck may include a substrate stage having a ceramic material and a base plate having a metal material. When a semiconductor manufacturing process is performed, heat may be applied to the substrate stage and the base plate. Since the substrate stage and the base plate have different thermal expansion coefficients, warpage may occur in the electrostatic chuck due to the application of the heat.

### SUMMARY

Example embodiments provide a substrate support apparatus having support structures that space a substrate stage and a base plate having different thermal expansion coefficients apart from each other.

Example embodiments provide a substrate processing apparatus including the substrate support apparatus.

According to example embodiments, a substrate support apparatus includes a base plate disposed in a space for performing a semiconductor process, a substrate stage disposed apart from the base plate, the substrate stage having a seating surface on an upper surface of the substrate stage, and a plurality of support structures arranged in a circumferential direction on the base plate to support the substrate stage on the base plate, the plurality of support structures extending in a radial direction to have a predetermined inclination angle from a surface of the base plate.

According to example embodiments, a substrate processing apparatus includes a chamber providing a space for performing a semiconductor process, a base plate disposed in the chamber, a substrate stage disposed apart from the base plate, the substrate stage having an upper surface for supporting the semiconductor substrate and a lower surface opposite to the upper surface, and a plurality of support structures arranged in a circumferential direction to support the substrate stage apart from the base plate, the plurality of support structures extending in a radial direction to have a predetermined inclination angle with respect to a surface of the base plate, the plurality of support structures having first end portions bonded to the lower surface of the substrate stage.

According to example embodiments, a substrate processing apparatus include a chamber providing a space for performing a semiconductor process on a semiconductor substrate, a base plate disposed in the chamber, a substrate stage disposed apart from the base plate, the substrate stage having a seating surface for supporting the semiconductor substrate, a plurality of support structures arranged in a circumferential direction to support the substrate stage apart from the base plate, the plurality of support structures extending radially from a surface of the base plate to have a predetermined inclination angle with respect to the base plate, the plurality of support structures having first end portions bonded to a lower surface of the substrate stage, and a guide structure disposed on the base plate, the guide structure configured to be brought in contact with or to be spaced apart from the substrate stage according to a bending of the plurality of support structures.

According to example embodiments, a substrate stage may be spaced apart from a base plate by a plurality of support structures. The substrate stage may include a ceramic material that satisfies conditions such as electrical conductivity and thermal conductivity. The base plate may include a metal material to implement desired functions. In a high temperature process, the substrate stage and the base plate having different thermal expansion coefficients may be spaced apart by the plurality of support structures. The plurality of support structures may offset a deformation difference of the substrate stage and the base plate in the high temperature process. Further, the high temperature process may be stably performed on the semiconductor substrate.

Furthermore, heat transfer from the substrate stage to the base plate may be limited. The predetermined inclination angles of the support structures may be increased or decreased, and accordingly, effects of increasing cooling efficiency or reducing heat loss may be selectively obtained in the semiconductor process.

### BRIEF DESCRIPTION OF THE DRAWINGS

Example embodiments will be more clearly understood from the following detailed description taken in conjunction with the accompanying drawings. FIGS. 1 to 10 represent non-limiting, example embodiments as described herein.

FIG. 1 is a view illustrating a substrate processing apparatus having a substrate support apparatus in accordance with example embodiments.

FIG. 2 is a plan view illustrating a base plate in FIG. 1, wherein a plurality of support structures are disposed on the base plate.

FIG. 3 is a perspective view illustrating the support structure in FIG. 2.

FIG. 3 is a perspective view illustrating the support structure in FIG. 1.

FIG. 4 is an enlarged cross-sectional view illustrating portion ‘A’ in FIG. 1.

FIG. 5 and FIG. 6 are enlarged cross-sectional views illustrating portion ‘A’ in FIG. 1 in a process in which the support structure increases a cooling efficiency.

FIG. 7 and FIG. 8 are enlarged cross-sectional views illustrating portion ‘A’ in FIG. 1 in a process in which the support structure reduces heat loss.

FIG. 9 is a view illustrating a substrate processing apparatus having a substrate support apparatus in accordance with example embodiments.

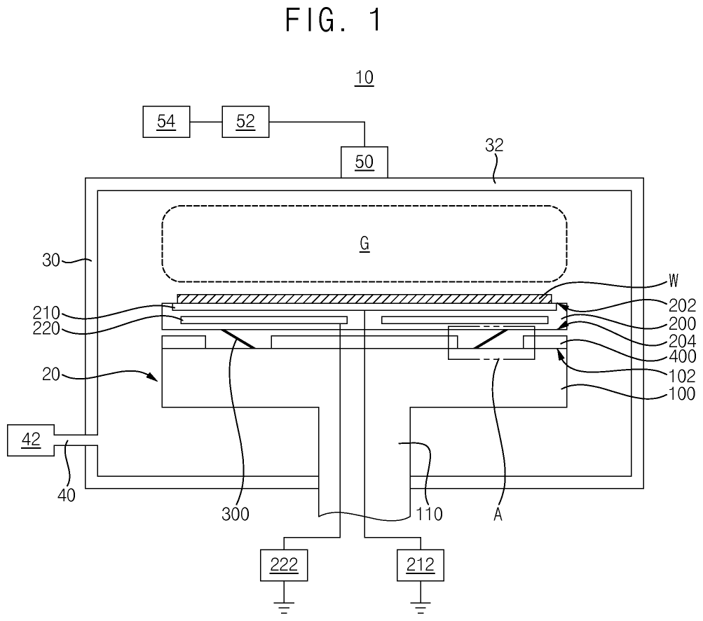

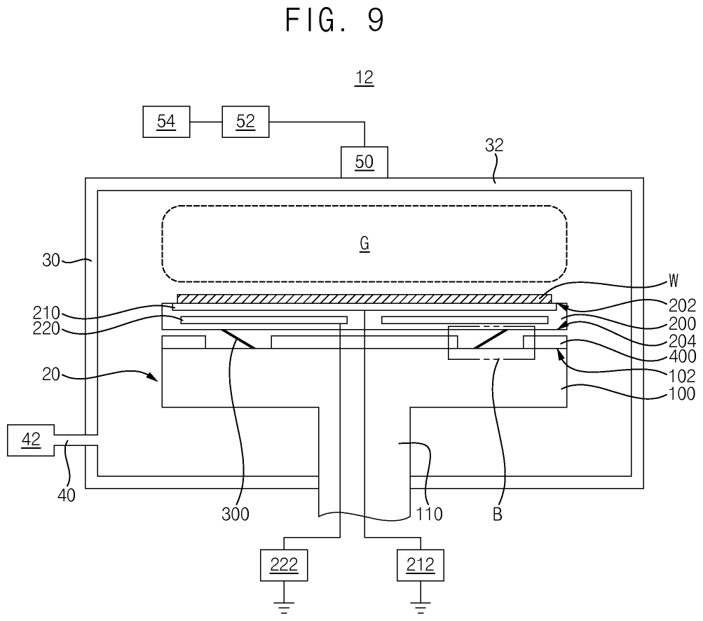

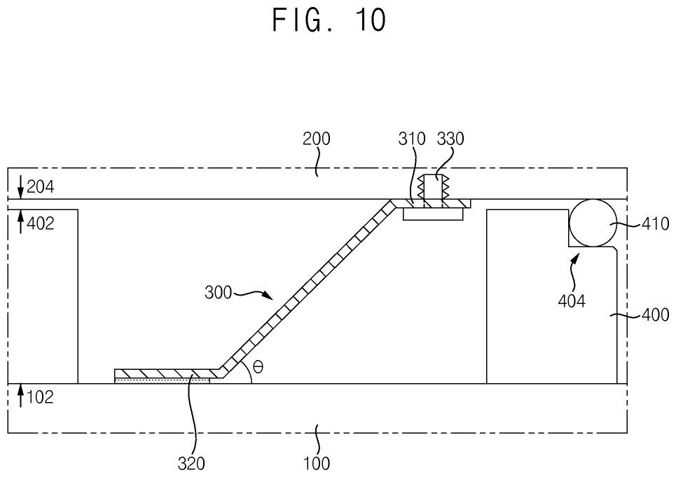

FIG. 1θ is an enlarged cross-sectional view illustrating portion ‘B’ in FIG. 9.

### DETAILED DESCRIPTION

Hereinafter, example embodiments will be explained in detail with reference to the accompanying drawings. The same reference numerals are used for the same components in the drawings, and redundant descriptions of the same components may be omitted. In this specification, it will be understood that when an element referred to as being “on”, “connected to”, or “coupled to” another element, may be directly on, connected, or coupled to the other element, or one or more intervening elements may also be present.

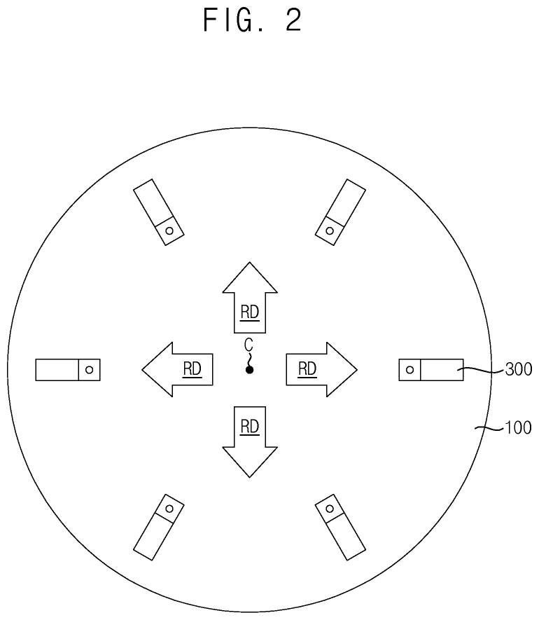

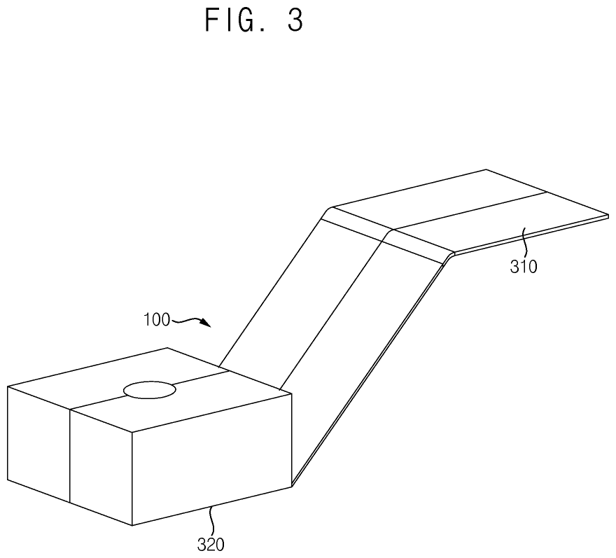

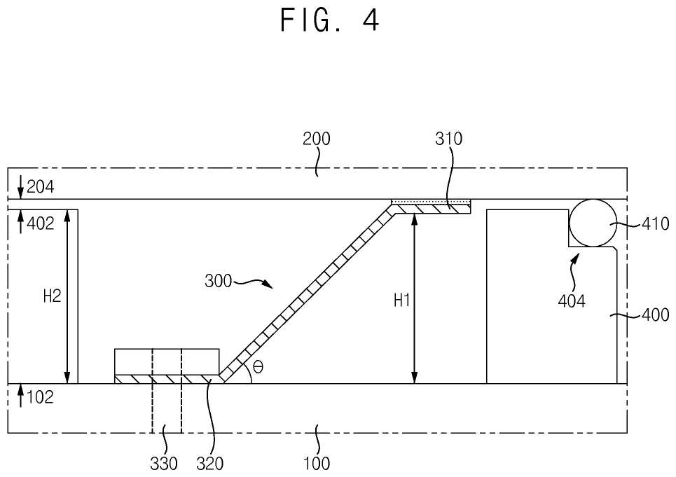

FIG. 1 is a view illustrating a substrate processing apparatus having a substrate support apparatus in accordance with example embodiments. FIG. 2 is a plan view illustrating a base plate in FIG. 1 and a plurality of support structures. FIG. 3 is a perspective view illustrating the support structure in FIG. 2. FIG. 4 is an enlarged cross-sectional view illustrating portion ‘A’ in FIG. 1.

Referring to FIGS. 1 to 4, a substrate processing apparatus 10 may include a chamber 30. The chamber 30 may be configured to provide a space for performing a semiconductor process such as an etching process on a semiconductor substrate W, and a substrate support apparatus 20 configured to support the semiconductor substrate W.

In example embodiments, the substrate processing apparatus 10 may be referred to as an apparatus for etching an etch target layer on the semiconductor substrate W disposed in the chamber 30. The substrate processing apparatus 10 may perform a plasma process on the semiconductor substrate W. The substrate processing apparatus 10 may etch the etch target layer using plasma. For example, the substrate processing apparatus 10 may generate inductively coupled plasma (ICP), capacitively coupled plasma (CCP), or microwave plasma. In addition, the substrate processing apparatus may not be limited to an etching apparatus, and may be used as, for example, a deposition apparatus, a cleaning apparatus, etc. The semiconductor substrate may include a silicon substrate, a glass substrate, etc.

The substrate processing apparatus 10 may perform the semiconductor process on the semiconductor substrate W in a high-temperature environment within the chamber 30. The chamber 30 may be heated by the plasma or the like. Alternatively, the substrate processing apparatus 10 may perform the semiconductor process on the semiconductor substrate W in an ultra-low temperature environment (e.g., −100° C.) within the chamber 30.

In example embodiments, the chamber 30 may provide an enclosed space for performing the etching process on the semiconductor substrate W. An environment within the chamber 30 may be controlled. For example, a high-temperature environment or an ultra-low temperature environment may be established within the chamber 30. The chamber 30 may include a cylindrical vacuum chamber. The chamber 30 may include a metal such as aluminum or stainless steel.

The substrate support apparatus 20 for supporting the semiconductor substrate W may be disposed in the chamber 30. For example, the substrate support apparatus 20 may serve as a susceptor for supporting the semiconductor substrate W.

A door may be installed in a sidewall of the chamber 30 to allow the semiconductor substrate W to pass therethrough. The semiconductor substrate W may be loaded and unloaded onto and from the substrate support apparatus 20 through the door. The door may be opened to allow the semiconductor substrate W to pass into, or out of, the chamber 30. The door may be closed to seal the chamber 30, providing an enclosed space for performing the etching process on the semiconductor substrate W.

An exhaust port 40 may be installed in the chamber 30. The exhaust port 40 may be installed in a lower portion of the chamber 30. An exhaust portion 42 may be connected to the exhaust port 40. An exhaust pipe (not illustrated) may connect the exhaust port 40 the exhaust portion 42. The exhaust portion 42 may include a vacuum pump such as a turbo molecular pump to adjust a vacuum within a processing space inside the chamber 30. The vacuum pump may be used to adjust the environment within the processing space inside the chamber 30 to a desired vacuum level. In addition, process by-products and residual process gases generated in the chamber 30 may be discharged through the exhaust port 40 and the exhaust portion 42.

The chamber 30 may include a cover 32. The cover 32 may cover an upper portion of the chamber 30. The cover 32 may seal the upper portion of the chamber 30.

In example embodiments, the substrate processing apparatus 10 may further include a gas supply portion. The gas supply portion may be configured to supply gas into the chamber 30. For example, the gas supply portion may include gas supply pipes 50, a flow controller 52, and a gas supply source 54 as gas supply elements. The gas supply pipes 50 may supply various gases to the chamber 30. The gas supply pipes 50 may supply various gases to a top portion and/or a side portion of the chamber 30. For example, the gas supply pipes may include a vertical gas supply pipe that penetrates the cover 32, and a horizontal gas supply pipe that penetrates the sidewall of the chamber 30. The vertical gas supply pipe and the horizontal gas supply pipe may directly supply various gases G into the chamber 30.

The gas supply portion may supply different gases. The gas supply portion may supply the different gases at a desired ratio. The gas supply source 54 may store a plurality of gases, and the gases may be supplied through a plurality of gas lines respectively connected to the gas supply pipes 50. The flow controller 52 may control supply flow rates of gases that are introduced into the chamber 30 through the gas supply pipes 50. The flow controller 52 may independently or commonly control the supply flow rates of gases that are respectively supplied to the vertical gas supply pipe and the horizontal gas supply pipe. For example, the gas source 54 may include a plurality of gas tanks, and the flow controller 52 may include a plurality of mass flow controllers (MFCs) respectively corresponding to the plurality of gas tanks. The mass flow controllers may independently control the supply flow rates of the gases.

In example embodiments, the substrate support apparatus 20 may be provided in the chamber 30 to support the semiconductor substrate W. The substrate support apparatus 20 may include a base plate 100 disposed in the chamber 30, a substrate stage 200 disposed apart from the base plate 100, and a plurality of support structures 300 configured to support the substrate stage 200 on the base plate 100.

The substrate support apparatus 20 may undergo thermal expansion due to heat that is generated during the semiconductor process. The substrate support apparatus 20 may be thermally expanded by heat of the plasma. Components of the substrate support apparatus 20 may be deformed differently depending on different thermal expansion coefficients. The substrate support apparatus 20 may be thermally deformed in an ultra-low temperature environment in a similar manner as in a high temperature environment. The base plate 100 may be disposed in a space for performing the semiconductor process on the semiconductor substrate W. The base plate 100 may be supported by a support shaft 110. For example, a lower surface of the base plate 100 may be supported by a support shaft 110. The base plate 100 may rotate by a rotational driving force from the support shaft 110. For example, the base plate 100 may be rotated clockwise or counterclockwise by the support shaft 110.

The base plate 100 may include a metal material. The metal material may have a first thermal expansion coefficient. For example, the metal material may include metal oxides, metal nitrides, metal oxynitrides, or an alloy thereof. The metal material may include nickel (Ni), antimony (Sb), bismuth (Bi), zinc (Zn), indium (In), palladium (Pd), platinum (Pt), aluminum (Al), copper (Cu), Molybdenum (Mo), titanium (Ti), gold (Au), silver (Ag), chromium (Cr), tin (Sn), or an alloy thereof.

The base plate 100 may undergo thermal expansion due to heat of the plasma generated in the plasma process. The base plate 100 may expand in a radial direction RD to be deformed due to the thermal expansion of the base plate 100. The degree of deformation of the thermal expansion of the base plate 100 may vary depending on the first thermal expansion coefficient.

In example embodiments, the substrate stage 200 may be disposed apart from the base plate 100 by the plurality of support structures 300. The substrate stage 200 may have an upper surface 202 (e.g., a seating surface) and a lower surface 204 opposite to the upper surface 202. The upper surface 202 of the substrate stage 200 may be referred to as a seating surface on which the semiconductor substrate W may be supported.

The substrate stage 200 may rotate by the rotational driving force from the base plate 100. For example, the substrate stage 200 may be rotated clockwise or counterclockwise by the base plate 100.

The substrate stage 200 may include a ceramic material. The ceramic material may have a second thermal expansion coefficient. The second thermal expansion coefficient may be different from the first thermal expansion coefficient of the metal material. For example, the ceramic material may include aluminum, aluminum oxide, aluminum nitride, aluminum oxynitride, or an alloy thereof.

For example, when the substrate stage 200 includes the aluminum nitride, the second thermal expansion coefficient of the substrate stage 200 may be about 5.1 ppm/° C. (parts per million per degree Celsius temperature change).

The substrate stage 200 may further include a support electrode 210 and a resistive heating element 220. The support electrode 210 may be configured to magnetically hold the semiconductor substrate W to the seating surface. The resistive heating element 220 may be configured to control a temperature of the semiconductor substrate W. The substrate stage 200 may be provided in the chamber 30 to support the semiconductor substrate W, and may control the temperature of the substrate stage 200 during the etching process.

The support electrode 210 may be provided adjacent to the seating surface. The support electrode 210 may be configured to hold the semiconductor substrate W with constant power. The support electrode 210 may be configured to hold the semiconductor substrate W with constant power through a DC voltage that may be supplied from a DC power supply. The support electrode 210 may provide the seating surface. The seating surface may be configured to directly contact and support the semiconductor substrate W. Alternatively, the support electrode 210 may be embedded within the substrate stage 200 to support the semiconductor substrate W. For example, the support electrode 210 may be connected to a first power supply 212 to receive the DC voltage for generating electrostatic force.

For example, after the semiconductor substrate W is placed on the support electrode 210, a predetermined voltage may be applied from the DC power supply. When the predetermined voltage is applied, a potential difference may occur between the semiconductor substrate W and the support electrode 210 due to the high DC voltage. The potential difference may generate a dielectric polarization inside an insulator of the support electrode 210. An electrostatic force may be generated by the dielectric polarization, and the support electrode 210 may hold the semiconductor substrate W through the electrostatic force.

When the etching process is finished, the support electrode 210 may remove the electrostatic force to de-chuck of the semiconductor substrate W. The first power supply 212 may block the voltage provided to the support electrode 210. For example, after the etching process is finished, the first power supply 212 may block the voltage provided to the support electrode 210.

The support electrode 210 may have a circulation channel for controlling a temperature of the support electrode 210. The support electrode 210 may have a circulation channel for cooling of the support electrode 210. Additionally, for precise control of the temperature of the semiconductor substrate, a cooling gas such as He gas may be supplied between the support electrode 210 and the semiconductor substrate W.

The resistive heating element 220 may be disposed adjacent to the seating surface. The resistive heating element 220 may be disposed under the support electrode 210. The resistive heating element 220 may be embedded within the substrate stage 200. The resistive heating element 220 may generate heat through a DC voltage that may be supplied from a DC power source. The resistive heating element 220 may transfer heat to the semiconductor substrate W. For example, the resistive heating element 220 may be connected to a second power supply 222 to receive power for generating heat.

The substrate stage 200 may undergo thermal expansion due to heat of the plasma that may be generated in the plasma process. The substrate stage 200 may undergo the thermal expansion by heat transferred from the resistive heating element 220. The substrate stage 200 may expand in the radial direction RD to be deformed due to the thermal expansion of the substrate stage 200. The degree of deformation of the thermal expansion of the substrate stage 200 may vary depending on the second thermal expansion coefficient. Since the second thermal expansion coefficient of the substrate stage 200 and the first thermal expansion coefficient of the base plate 100 may be different from each other, the degrees of deformation of the substrate stage 200 and the base plate 100 may be different from each other.

In example embodiments, the plurality of support structures 300 may support the substrate stage 200 on the base plate 100. The plurality of support structures 300 may extend in a substantially radial direction RD from a center C of the base plate 100. The plurality of support structures 300 may extend in other directions around the center C of the base plate 100.

The plurality of support structures 300 may be arranged along a circumferential direction on the base plate 100. The plurality of support structures 300 may be arranged to stably support the substrate stage 200. The plurality of support structures 300 may be arranged at a predetermined interval along the circumferential direction.

A predetermined number of the plurality of support structures 300 may be arranged on the base plate 100. When the predetermined number increases, the plurality of support structures 300 may increase resistance to external force. When the predetermined number is reduced, over-constraint of the plurality of support structures 300 may be reduced, and positioning accuracy may be improved. For example, the predetermined number of the plurality of support structures 300 may be in a range of about 3 to 16.

The plurality of support structures 300 may extend from the surface 102 of the base plate 100 to have a predetermined inclination angle θ with respect to the surface 102. First end portions 310 of the plurality of support structures 300 may support the lower surface 204 of the substrate stage 200, and second end portions 320 of the plurality of support structures 300 opposite to the first end portions 310 may support the base plate 100. The first end portions 310 of the plurality of support structures 300 may have a first height H1 from the surface 102 of the base plate 100. For example, the first height H1 may be within a range of about 8 millimeters (mm) to 20 mm.

The predetermined inclination angle θ of each of the plurality of support structures 300 may be changed according to an external force applied from the substrate stage 200. The external force may be a weight of the semiconductor substrate W is placed on the substrate stage 200. For example, when the semiconductor substrate W is placed on the substrate stage 200, the predetermined inclination angles θ of the plurality of support structures 300 may decrease. The plurality of support structures 300 may rotate about the second end portions 320. The plurality of support structures 300 may rotate about the second end portions 320 and may bend and deform in the radial direction, by decreasing the predetermined inclination angle θ. The plurality of support structures 300 may rotate around the second end portions 320 and may reduce an impact applied from the substrate stage 200.

The first end portions 310 of the plurality of support structures 300 may be directly bonded to the lower surface 204 of the substrate stage 200. The first end portions 310 of the plurality of support structures 300 may be directly bonded to the lower surface 204 of the substrate stage 200 by brazing bonding. In a case where the plurality of support structures 300 are bonded to the lower surface 204 of the substrate stage 200 by the brazing bonding, the plurality of support structures 300 and the substrate stage 200 may be bonded to each other without fastening elements. In a case where the plurality of support structures 300 and the substrate stage 200 are directly bonded to each other without the fastening elements, failures such as distortion, defective bonding, etc., between the plurality of support structures 300 and the substrate stage 200 that may be caused by a difference in thermal expansion coefficient of the fastening elements may be reduced or prevented.

The second end portions 320 of the plurality of support structures 300 may be bonded to the surface 102 of the base plate 100. The second end portions 320 of the plurality of support structures 300 may be bonded to the surface 102 of the base plate 100 by a plurality of bolts 330. In a case where the plurality of support structures 300 are bonded to the surface 102 of the base plate 100 by the plurality of bolts 330, the plurality of support structures 300 and the base plate 100 may be strongly bonded. In a case where the plurality of support structures 300 are strongly bonded on the surface 102 of the base plate 100 by the plurality of bolts 330, the plurality of support structures 300 may have high resistance to the external force that may be generated from the substrate stage 200.

In a case where the second end portions 320 of the plurality of support structures 300 are spaced apart from the substrate stage 200, the plurality of bolts 330 may receive less heat generated from the plasma process. In a case where the plurality of bolts 330 receive less heat from the substrate stage 200, the plurality of bolts 330 may undergo reduced thermal expansion, and the plurality of support structures 300 may be strongly fixed to the base plate 100.

The heat generated by the plasma that may be generated in the plasma process may cause additional thermal expansion in the substrate stage 200 than in the base plate 100. Accordingly, the plurality of support structures 300 may be more affected by the deformation of the substrate stage 200 than the deformation of the base plate 100.

The plurality of support structures 300 may include a first elastic material. The first elastic material may have a third thermal expansion coefficient. The third thermal expansion coefficient may be different from the first thermal expansion coefficient of the metal material and the second thermal expansion coefficient of the ceramic material. The third thermal expansion coefficient may be closer to the second thermal expansion coefficient than the first thermal expansion coefficient.

In a case that the third thermal expansion coefficient is closer to the second thermal expansion coefficient than the first thermal expansion coefficient, a difference in thermal deformation between the plurality of support structures 300 and the substrate stage 200 may be relatively small. In a case that the difference of the thermal deformation between the plurality of support structures 300 and the substrate stage 20θ is relatively small, damage to the plurality of support structures 300 due to the difference of the thermal deformation may be reduced or prevented. For example, the first elastic material may include a kovar material.

For example, when the substrate stage 200 includes the aluminum nitride, the plurality of support structures 300 may include the kovar material. In this case, the second thermal expansion coefficient of the substrate stage 200 may be about 5.1 ppm/° C., and the third thermal expansion coefficient of the plurality of support structures 300 may be about 6.0 ppm/° C.

In example embodiments, the substrate support apparatus 20 may further include a guide structure 400 and a sealing member 410. The guide structure 400 may be disposed on the base plate 100. The sealing member 410 may be an O-ring disposed between the guide structure 400 and the substrate stage 200.

When the plurality of support structures 300 are pressed down by the substrate stage 200, the guide structure 400 may support the substrate stage 200. For example, the guide structure 400 may support a central region of the substrate stage 200 and a peripheral region surrounding the central region.

An upper surface 402 of the guide structure 400 may have a second height H2 from the surface 102 of the base plate 100. The second height H2 of the guide structure 400 may be less than the first height H1 of the plurality of support structures 300. In a case that the second height H2 of the guide structure 40θ is less than the first height H1 of the plurality of support structures 300, the substrate stage 200 may be supported by the plurality of support structures 300. When the predetermined inclination angle θ of the plurality of support structures 30θ is reduced, the lower surface 204 of the substrate stage 200 may be brought in contact with the upper surface 402 of the guide structure 400. For example, the second height H2 may be within a range of about 5 mm to 20 mm.

The guide structure 400 may include a metal material. The metal material may have high thermal conductivity. When the substrate stage 20θ is brought in contact with the guide structure 400, the guide structure 400 may receive heat from the substrate stage 200 due to the high thermal conductivity. The guide structure 400 may increase a cooling efficiency of the substrate stage 200 through the high thermal conductivity.

The sealing member 410 may be disposed in a groove 404 of the guide structure 400. The sealing member 410 may support the peripheral region of the substrate stage 200 on the groove 404 of the guide structure 400. The sealing member 410 may seal between the guide structure 400 and the substrate stage 200, and the sealing member 410 may prevent foreign substances from entering between the guide structure 400 and the substrate stage 200. For example, the sealing member 410 may contact the substrate stage 200 and the guide structure 400 even when the substrate stage 20θ is disposed apart from the guide structure 400. The sealing member 410 may include a second elastic material. The sealing member 410, which may be an elastic sealing member, may absorb shock generated between the guide structure 400 and the substrate stage 200 through the second elastic material. The sealing member 410, which may be an elastic sealing member, may be deformed when the substrate stage 20θ is pressed toward the guide structure 400 and the base 100. For example, the second elastic material may include a rubber material.

Hereinafter, a method of supporting the substrate stage through the plurality of support structures will be described in detail.

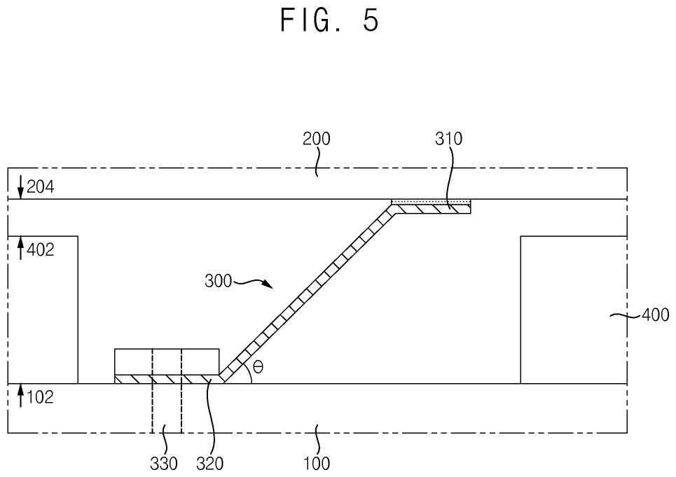

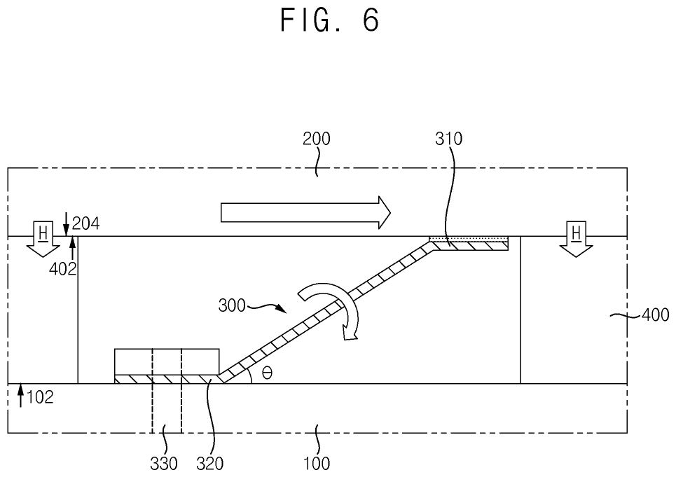

FIG. 5 and FIG. 6 are enlarged cross-sectional views illustrating portion ‘A’ shown in FIG. 1 in a process in which the support structure may increase a cooling efficiency.

Referring to FIGS. 1 to 6, the substrate processing apparatus 10 may be used as the etching apparatus. When the substrate processing apparatus 1θ is used as the etching apparatus, heat may be generated on the substrate stage 200 from plasma. The heat generated on the substrate stage 200 may be transferred to the semiconductor substrate W in the etching process, and a defect may occur in the semiconductor substrate W that is supported on the substrate stage 200.

As illustrated in FIG. 5 and FIG. 6, the substrate stage 200 may expand in the radial direction RD from the center C of the substrate stage 200 by heat according to a coefficient of thermal expansion.

The predetermined inclination angle θ of the plurality of support structures 300 may be within a range of about 20 degrees to 60 degrees. When the predetermined inclination angle θ is within the range of about 20 degrees to 60 degrees, the plurality of support structures 300 may expand together in the radial direction RD by expansion of the substrate stage 200.

In particular, since the second end portions 320 of the plurality of support structures 300 may be fixed on the base plate 100 and the first end portions 310 may be fixed on the lower surface 204 of the substrate stage 200, the first end portions 310 of the plurality of support structures 300 may move in the radial direction RD according to the expansion of the substrate stage 200. The plurality of support structures 300 may be rotated relative to the second end portions 320, that is, may bend and deform in the radial direction, by the expansion of the substrate stage 200.

When the plurality of support structures 300 are rotated (bent), the lower surface 204 of the substrate stage 200 may be brought into contact with the upper surface 402 of the guide structure 400. When the substrate stage 200 contacts the guide structure 400, heat H of the substrate stage 200 may be transferred to the guide structure 400 through conduction. For example, the plurality of support structures 300 having a temperature of about 200° C. may be disposed apart from the upper surface 402 of the guide structure 400, and the plurality of support structures 300 having a temperature of about 400° C. may be brought in contact with the upper surface 402 of the guide structure 400.

When the substrate stage 200 contacts the guide structure 400, the guide structure 400 may be heated by the substrate stage 200 through the high thermal conductivity. Thus, when the predetermined inclination angle θ of the plurality of support structures 30θ is within the range of about 20 degrees to 60 degrees, the plurality of support structures 300 may improve the cooling efficiency of the substrate stage 200. For example, heat transfer rates of the plurality of support structures 300 may be selectively controlled such that the substrate stage 20θ is brought into contact with the guide structure 400 within a range of about 200° C. to 400° C.

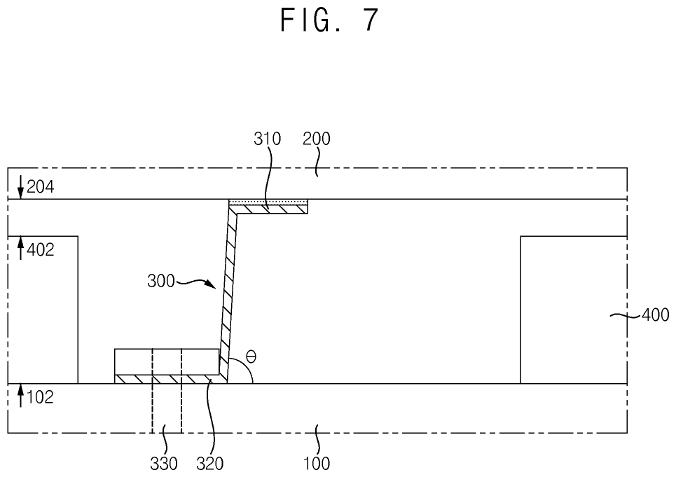

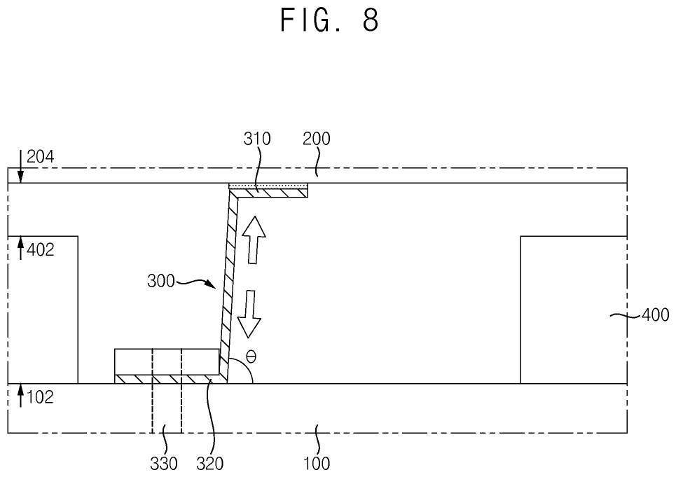

FIG. 7 and FIG. 8 are enlarged cross-sectional views illustrating portion ‘A’ in FIG. 1 in a process in which the support structure reduces heat loss.

Referring to FIGS. 1 to 4, 7 and 8, the substrate processing apparatus 10 may be used as the deposition apparatus. The substrate processing apparatus 10 may perform a chemical vapor deposition (CVD) process. When the substrate processing apparatus 1θ is used as the deposition apparatus, heat may be generated on the substrate stage 200 from the resistive heating element 220. The heat generated on the substrate stage 200 may be transferred to the semiconductor substrate W in the deposition process, and deposition efficiency on the semiconductor substrate W may be improved.

As illustrated in FIG. 7 and FIG. 8, the guide structure 400 may expand in a longitudinal direction by the heat.

The predetermined inclination angle θ of the plurality of support structures 300 may be within a range of about 60 degrees to 90 degrees. When the predetermined inclination angle θ is within the range of about 60 degrees to 90 degrees, the plurality of support structures 300 may expand due to heat and may move the substrate stage 200 away from the guide structure 400.

In particular, since the second end portions 320 of the plurality of support structures 300 are fixed on the base plate 100 and the first end portions 310 of the plurality of support structures 300 are fixed on the lower surface 204 of the substrate stage 200, distances between the first end portions 310 and the second end portions 320 may increase due to the heat.

When the distances between the first end portions 310 and the second end portions 320 increase, the lower surface 204 of the substrate stage 200 may be moved away from the upper surface 402 of the guide structure 400. For example, the plurality of support structures 300 may be spaced apart from the guide structure 400 by a predetermined distance at 200° C., and the predetermined distance may be increased at 400° C.

When the substrate stage 20θ is spaced apart from the guide structure 400, transfer of heat between the substrate stage 200 and the guide structure 400 may be reduced. Accordingly, when the predetermined inclination angle θ of the plurality of support structures 30θ is within the range of about 60 degrees to 90 degrees, the plurality of support structures 300 may reduce heat loss of the substrate stage 200. For example, heat transfer rates of the plurality of support structures 300 may be selectively controlled such that the plurality of support structures 300 are spaced apart from the guide structure 400 by the predetermined distance within the range of about 200 degrees to 400 degrees.

As mentioned, the substrate stage 200 may be spaced apart from the base plate 100 by the plurality of support structures 300. The substrate stage 200 may include the ceramic material that satisfies conditions such as electrical conductivity and thermal conductivity. The base plate 100 may include the metal material to implement desired functions. In the high temperature process, the substrate stage 200 and the base plate 100 having different thermal expansion coefficients may be spaced apart from each other by the plurality of support structures 300. In a case that the substrate stage 200 and the base plate 100 are spaced apart by the plurality of support structures 300, the plurality of support structures 300 may offset the deformation difference between the substrate stage 200 and the base plate 100 in the high temperature process. In a case that the plurality of support structures 300 are deformed and offset the deformation difference, the high temperature process may be stably performed on the semiconductor substrate W.

Additionally, in a case that the substrate stage 200 and the base plate 100 are connected through the plurality of support structures 300, the heat transfer from the substrate stage 200 to the base plate 100 may be reduced or limited. The predetermined inclination angles θ of the support structures 300 may be increased or decreased, and accordingly, effects of increasing cooling efficiency or reducing heat loss may be selectively obtained in the semiconductor process. For example, the support structures 300 may be bent due to an application of heat, and accordingly, effects of increasing cooling efficiency or reducing heat loss may be selectively obtained in the semiconductor process.

FIG. 9 is a view illustrating a substrate processing apparatus having a substrate support apparatus in accordance with example embodiments. FIG. 1θ is an enlarged cross-sectional view illustrating portion ‘B’ in FIG. 9. The substrate processing apparatus may be substantially the same as or similar to the substrate processing apparatus described with reference to FIGS. 1 to 4.

Referring to FIG. 9 and FIG. 10, a substrate processing apparatus 12 may include a chamber 30 configured to provide a space for performing a semiconductor process such as an etching process on a semiconductor substrate W, and a substrate support apparatus 20 configured to support the semiconductor substrate W.

The substrate support apparatus 20 may be provided in the chamber 30 to support the semiconductor substrate W. The substrate support apparatus 20 may include a base plate 100 disposed in the chamber 30, a substrate stage 200, and a plurality of support structures 300 configured to support the substrate stage 200 on the base plate 100. The substrate stage 200 may be disposed apart from the base plate.

First end portions 310 of the plurality of support structures 300 may be directly bonded to a lower surface 204 of the substrate stage 200 by a plurality of bolts 330. In a case that the plurality of support structures 300 are bonded to the lower surface 204 of the substrate stage 200 by the plurality of bolts 330, the plurality of support structures 300 and the substrate stage 200 may be strongly bonded to each other. In a case that the plurality of support structures 300 are strongly bonded on the lower surface 204 of the substrate stage 200 by the plurality of bolts 330, the plurality of support structures 300 may have high resistance to an external force generated from the substrate stage 200.

Second end portions 320 of the plurality of support structures 300 may be directly bonded to a surface 102 of the base plate 100 by brazing bonding. In a case that the plurality of support structures 300 are bonded to the surface 102 of the base plate 100 by the brazing bonding, the plurality of support structures 300 and the substrate stage 200 may be bonded to each other without fastening elements. In a case that the plurality of support structures 300 and the base plate 100 are bonded to each other without the fastening elements, failures such as distortion, defective bonding, etc., between the plurality of support structures 300 and the base plate 100 that may be caused by a difference in thermal expansion coefficient of the fastening elements may be reduced or prevented.

The foregoing is illustrative of example embodiments and is not to be construed as limiting thereof. Although example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A substrate support apparatus, comprising:
a base plate disposed in a space for performing a semiconductor process;
a substrate stage disposed apart from the base plate, the substrate stage having a seating surface on an upper surface of the substrate stage; and
a plurality of support structures arranged in a circumferential direction on the base plate to support the substrate stage on the base plate, the plurality of support structures extending in a radial direction to have a predetermined inclination angle with respect to a surface of the base plate.

2. The substrate support apparatus of claim 1, wherein first end portions of the plurality of support structures are bonded to the substrate stage.

3. The substrate support apparatus of claim 2, wherein second end portions opposite to the first end portions of the plurality of support structures are bonded to the substrate stage.

4. The substrate support apparatus of claim 1, wherein the base plate has a first thermal expansion coefficient, and
the substrate stage has a second thermal expansion coefficient different from the first thermal expansion coefficient.

5. The substrate support apparatus of claim 4, wherein the plurality of support structures have a third thermal expansion coefficient different from the first thermal expansion coefficient and the second thermal expansion coefficient, and
the third thermal expansion coefficient is closer to the second thermal expansion coefficient than the first thermal expansion coefficient.

6. The substrate support apparatus of claim 1, wherein the base plate includes at least one of nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), or tin (Sn).

7. The substrate support apparatus of claim 1, wherein the substrate stage includes at least one of aluminum, aluminum oxide, aluminum nitride, or aluminum oxynitride, and
the plurality of support structures include a kovar material.

8. The substrate support apparatus of claim 1, further comprising:
a guide structure disposed on the base plate and below the substrate stage; and
a sealing member provided between the guide structure and the substrate stage.

9. The substrate support apparatus of claim 1, wherein the predetermined inclination angle is within a range of about 20 degrees to 60 degrees.

10. The substrate support apparatus of claim 1, wherein the predetermined inclination angle is within a range of about 60 degrees to 90 degrees.

11. A substrate processing apparatus, comprising:
a chamber providing a space for performing a semiconductor process on a semiconductor substrate;
a base plate disposed in the chamber;
a substrate stage disposed apart from the base plate, the substrate stage having an upper surface for supporting the semiconductor substrate and a lower surface opposite to the upper surface; and
a plurality of support structures arranged in a circumferential direction to support the substrate stage apart from the base plate, the plurality of support structures extending in a radial direction to have a predetermined inclination angle with respect to a surface of the base plate, the plurality of support structures having first end portions bonded to the lower surface of the substrate stage.

12. The substrate processing apparatus of claim 11, wherein the first end portions of the plurality of support structures are bonded to the lower surface of the substrate stage by bolts.

13. The substrate processing apparatus of claim 11, wherein the base plate has a first thermal expansion coefficient, and
the substrate stage has a second thermal expansion coefficient different from the first thermal expansion coefficient.

14. The substrate processing apparatus of claim 13, wherein the plurality of support structures have a third thermal expansion coefficient different from the first thermal expansion coefficient and the second thermal expansion coefficient, and
the third thermal expansion coefficient is closer to the second thermal expansion coefficient than the first thermal expansion coefficient.

15. The substrate processing apparatus of claim 11, wherein the base plate includes at least one of nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), or tin (Sn).

16. The substrate processing apparatus of claim 11, wherein the substrate stage includes at least one of aluminum, aluminum oxide, aluminum nitride, or aluminum oxynitride, and
the plurality of support structures include a kovar material.

17. The substrate processing apparatus of claim 11, further comprising:
a guide structure disposed on the base plate and below the substrate stage; and
an elastic sealing member disposed between the guide structure and the substrate stage.

18. The substrate processing apparatus of claim 11, wherein the predetermined inclination angle is within a range of about 20 degrees to 60 degrees.

19. The substrate processing apparatus of claim 11, wherein the predetermined inclination angle is within a range of about 60 degrees to 90 degrees.

20. A substrate processing apparatus, comprising:
a chamber providing a space for performing a semiconductor process on a semiconductor substrate;
a base plate disposed in the chamber;
a substrate stage disposed apart from the base plate, the substrate stage having a seating surface for supporting the semiconductor substrate;
a plurality of support structures arranged in a circumferential direction to support the substrate stage apart from the base plate, the plurality of support structures extending radially from a surface of the base plate to have a predetermined inclination angle with respect to the base plate, the plurality of support structures having first end portions bonded to a lower surface of the substrate stage; and
a guide structure disposed on the base plate, the guide structure configured to be brought in contact with to or be spaced apart from the substrate stage according to a bending of the plurality of support structures.
